(19) United States
(12) Patent Application Publication
(10) Pub. No.: US 2025/0253638 A1
(43) Pub. Date: Aug. 7, 2025

(54) DETECTION CIRCUIT, SEMICONDUCTOR INTEGRATED CIRCUIT, SEMICONDUCTOR DEVICE, AND CONTROL METHOD

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Yoshiharu NITO, Yokohama (JP); Shoji OOTAKA, Yokohama (JP); Reiji TAGOMORI, Yokohama (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/190,923

(22) Filed: Apr. 28, 2025

Related U.S. Application Data
(63) Continuation of application No. PCT/JP2024/007617, filed on Feb. 29, 2024.

(30) Foreign Application Priority Data
Jul. 13, 2023 (JP) 2023-115298

(51) Int. Cl. H02H 1/00; H02H 9/02

(52) U.S. Cl. CPC H02H 1/0007; H02H 9/025

(57) ABSTRACT

According to one embodiment, there is provided a detection circuit including a comparison circuit and a signal generation circuit. The comparison circuit has a first input node, a second input node, and an output node. The first input node is connected to one end of a power device. The second input node is connected to a threshold voltage. The signal generation circuit has a first input node and an output node. The first input node is connected to the output node of the comparison circuit. The output node is connected to a control node of a protection circuit of the power device.

### CROSS-REFERENCE TO RELATED APPLICATIONS

This application is based upon and claims the benefit of priority from Japanese Patent Application No. 2023-115298, filed on Jul. 13, 2023; the entire contents of which are incorporated herein by reference.

### FIELD

Embodiments described herein relate generally to a detection circuit, a semiconductor integrated circuit, a semiconductor device, and a control method.

### BACKGROUND

A semiconductor device connected to a control terminal of a power device drives the power device. The power device is connected to a load through which a relatively large current flows, and is used to switch the load. In the semiconductor device, it is desirable to appropriately protect the power device from an overcurrent.

### BRIEF DESCRIPTION OF THE DRAWINGS

FIG. 1 is a circuit diagram illustrating a configuration of a semiconductor device according to an embodiment;

FIGS. 2A to 2D are diagrams illustrating the concept of DESAT in the embodiment;

FIG. 3 is a waveform diagram illustrating an operation of the semiconductor device according to the embodiment;

FIG. 4 is a circuit diagram illustrating a configuration of a semiconductor device according to a first modification of the embodiment;

FIG. 5 is a circuit diagram illustrating a configuration of a time history generation circuit in the first modification of the embodiment;

FIG. 6 is a waveform diagram illustrating an operation of the time history generation circuit according to the first modification of the embodiment;

FIG. 7 is a circuit diagram illustrating a configuration of a semiconductor device according to a second modification of the embodiment;

FIG. 8 is a circuit diagram illustrating a configuration of a semiconductor device according to a third modification of the embodiment;

FIG. 9 is a circuit diagram illustrating a configuration of a semiconductor device according to a fourth modification of the embodiment; and

FIG. 10 is a circuit diagram illustrating a configuration of a semiconductor device according to a fifth modification of the embodiment.

### DETAILED DESCRIPTION

In general, according to one embodiment, there is provided a detection circuit including a comparison circuit and a signal generation circuit. The comparison circuit has a first input node connected to one end of a power device. A second input node connected to a threshold voltage corresponding to a fall in a waveform, and an output node. The signal generation circuit has a first input node connected to the output node of the comparison circuit and an output node connected to a control node of a protection circuit of the power device.

Exemplary embodiments of a semiconductor device will be explained below in detail with reference to the accompanying drawings. The present invention is not limited to the following embodiments.

### Embodiment

The semiconductor device according to the embodiment is connected to a control terminal of a power device to drive the power device, and is devised to appropriately protect the power device from an overcurrent.

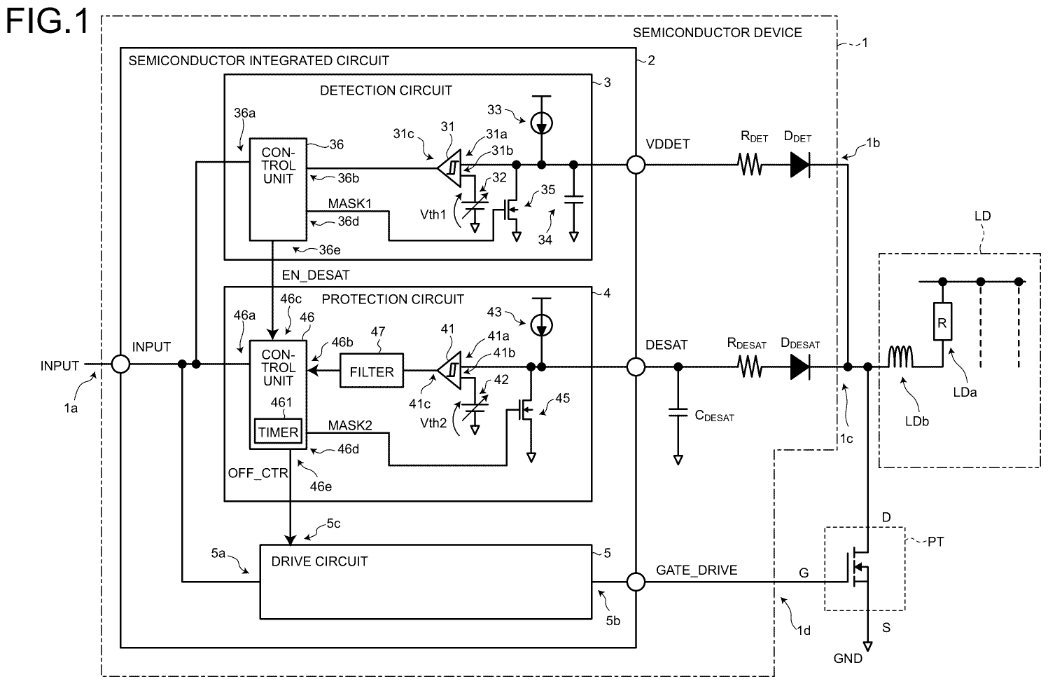

A semiconductor device 1 may be connected to a control terminal G of a power device PT, as illustrated in FIG. 1, to drive the power device PT. FIG. 1 is a circuit diagram illustrating a configuration of the semiconductor device 1.

The power device PT is connected to a load LD that operates at a relatively large current, and is used to switch the load LD. The load LD may include a resistance component LDa and an induction component LDb. For example, the load LD may be a DC motor and a part of its drive circuit (e.g., an H-bridge circuit), and the power device PT may be another part of the drive circuit.

Alternatively, the load LD may be an AC motor and a part of its drive circuit (e.g., an inverter circuit), and the power device PT may be another part of the drive circuit.

As the power device PT, any device capable of handling a relatively large current can be applied. The power device PT may be an insulated gate bipolar transistor (IGBT), a power metal-oxide-semiconductor field-effect transistor (MOSFET), or a bipolar transistor. The substrate used in the element structure of the power device PT may be a SiC substrate or a Si substrate.

If a failure such as a short circuit occurs in the load LD, an overcurrent may flow through the power device PT. In order to protect the power device PT from the overcurrent, it is effective to detect that the overcurrent starts to flow through the power device PT and perform a protection operation by turning off the power device PT accordingly. It is possible to detect that the overcurrent starts to flow through the power device PT by detecting DESAT (hereinafter, DESAT detection).

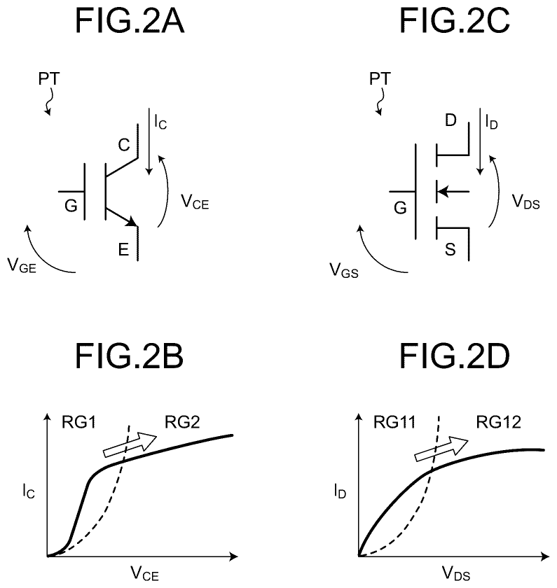

The DESAT may be defined as illustrated in FIGS. 2A to 2D. FIGS. 2A to 2D are diagrams for explaining the DESAT.

For example, in a case where the power device PT is an N-type IGBT, one end of the power device PT is a collector C, the other end of the power device PT is an emitter E, and the control terminal of the power device PT is a gate G as illustrated in FIG. 2A.

As illustrated in FIG. 2B, when the power device PT is turned on with a voltage V_{CE} between the gate G and the emitter E exceeding a predetermined value, a current I_{C} from the collector C to the emitter E sharply increases in response to an increase in voltage V_{CE} between the collector C and the emitter E in a region RG1. In a region RG2 on a higher voltage side, the current I_{C} gradually increases in response to the increase in the voltage V_{CE}.

As indicated by a white arrow in FIG. 2B, the transition from the region RG1 where the current I_{C} sharply increases to the region RG2 where the current I_{C} gradually increases will be referred to as DESAT. The region RG1 may be referred to as a saturation region. The region RG2 may be referred to as an active region.

Note that the case where the power device PT is a P-type IGBT is similar to the case where the power device PT is an N-type IGBT, except that the polarity of the voltage between the gate G and the emitter E at which the power device PT is turned on is reversed, and the collector current flows in a direction from the emitter E to the collector C.

Alternatively, in a case where the power device PT is an N-type power MOSFET, one end of the power device PT is a drain D, the other end of the power device PT is a source S, and the control terminal of the power device PT is a gate G as illustrated in FIG. 2C.

As illustrated in FIG. 2D, when the power device PT is turned on with a voltage Ves between the gate G and the source S exceeding a predetermined value, a current I_{D} of the drain D sharply increases in response to an increase in voltage V_{DS} between the drain D and the source S in a region RG11. In a region RG12 on a higher voltage side, the current I_{D} gradually increases in response to the increase in the voltage V_{DS}.

As indicated by a white arrow in FIG. 2D, the transition from the region RG11 where the current I_{D} sharply increases to the region RG12 where the current I_{D} gradually increases will be referred to as DESAT. The region RG11 may be referred to as a linear region. The region RG12 may be referred to as a saturation region.

Note that the case where the power device PT is a P-type power MOSFET is similar to the case where the power device PT is an N-type power MOSFET, except that the polarity of the voltage between the gate G and the source S at which the power device PT is turned on is reversed, and the drain current flows in a direction from the source S to the drain D.

Although not illustrated, in a case where the power device PT is a bipolar transistor, one end of the power device PT is a collector, the other end of the power device PT is an emitter, and the control terminal of the power device PT is a base. A transition from a region where the current sharply increases across both ends to a region where the current gradually increases across both ends will be referred to as DESAT.

Hereinafter, the case where the power device PT is an N-type power MOSFET will be mainly described. One end, the other end, and the control terminal of the power device PT are denoted by D, S, and G, respectively. The following description is also applicable to other types of power devices PT.

The semiconductor device 1 illustrated in FIG. 1 includes input nodes 1a to 1c and an output node 1d. The input node 1a is connected to the outside (e.g., a higher-level controller) and receives an input signal INPUT from the outside. The input node 1b is connected to the one end D of the power transistor PT and one end of the load LD. The input node 1c is connected to the one end D of the power transistor PT and one end of the load LD. The output node 1d is connected to the control terminal G of the power transistor PT.

The one end D of the power device PT is connected to the input nodes 1b and 1c of the semiconductor device 1 and one end of the load LD, the other end S of the power device PT is connected to a ground potential GND, and the control terminal G of the power device PT is connected to the output node 1d of the semiconductor device 1.

The semiconductor device 1 includes a semiconductor integrated circuit 2, a rectifier element D_{DESAT}, a capacitive element C_{DESAT}, a resistive element R_{DESAT}, a rectifier element D_{DET}, and a resistive element R_{DET}.

The semiconductor integrated circuit 2 may be configured as a single chip, or may be configured by dividing it into multiple chips. The semiconductor integrated circuit 2 has a terminal INPUT, a terminal VDDET, a terminal DESAT, and a terminal GATE_DRIVE.

The rectifier element D_{DESAT} is connected between the terminal DESAT and the one end D of the power device PT. The forward direction in the rectifier element D_{DESAT} is a direction from the terminal DESAT toward the one end D. The rectifier element D_{DESAT} may be a diode.

One end of the capacitive element C_{DESAT} is connected to a node between the terminal DESAT and the rectifier element D_{DESAT}, and the other end of the capacitive element C_{DESAT} is connected to the ground potential. The capacitance value of the capacitive element C_{DESAT} can be determined in advance according to an operation characteristic required for a protection circuit 4. The capacitance value of the capacitive element C_{DESAT} can be determined in advance according to a charge characteristic (e.g., an RC time constant or a charging time by a current source 43) of the capacitive element C_{DESAT} required for the DESAT detection of the power device PT.

The resistive element R_{DESAT} is connected between the terminal DESAT and the rectifier element D_{DESAT}. The resistance value of the resistive element R_{DESAT} can be determined in advance according to a characteristic required for the protection circuit 4. The resistance value of the resistive element R_{DESAT} can be determined in advance according to an operation characteristic required for the protection circuit 4. The resistance value of the resistive element R_{DESAT} can be determined in advance according to a charge characteristic (e.g., an RC time constant) of the capacitive element C_{DESAT} required for the DESAT detection of the power device PT.

The rectifier element D_{DET} is connected between the terminal VDDET and the one end D of the power device PT. The forward direction in the rectifier element D_{DET} is a direction from the terminal VDDET toward the one end D. The rectifier element D_{DET} may be a diode.

The resistive element R_{DET} is connected between the terminal VDDET and the rectifier element D_{DET}. The resistance value of the resistive element R_{DET} can be determined in advance according to an operation characteristic required for a detection circuit 3. The resistance value of the resistive element R_{DET} can be determined in advance according to a resistance characteristic (e.g., a transient current limit) of the resistive element R_{DET} required for detecting a fall in a voltage at the one end D of the power device PT.

The semiconductor integrated circuit 2 includes a detection circuit 3, a protection circuit 4, and a drive circuit 5.

The detection circuit 3 is connected between the terminal INPUT, the protection circuit 4, and the terminal VDDET. The detection circuit 3 can detect a fall in a voltage at one end D of the power device PT via the terminal VDDET. When detecting the fall in the voltage at the one end D, the detection circuit 3 generates a signal for enabling the protection circuit 4 and supplies the signal to the protection circuit 4.

The detection circuit 3 includes a comparison circuit 31, a voltage source 32, a current source 33, a capacitive element 34, a switch 35, and a control unit (signal generation circuit) 36.

The comparison circuit 31 has an input node 31a, an input node 31b, and an output node 31c. The input node 31a is connected to the one end D of the power device PT via the terminal VDDET, the resistive element R_{DET}, and the rectifier element D_{DET}. The input node 31b is connected to the voltage source 32. The output node 31c is connected to the control unit 36.

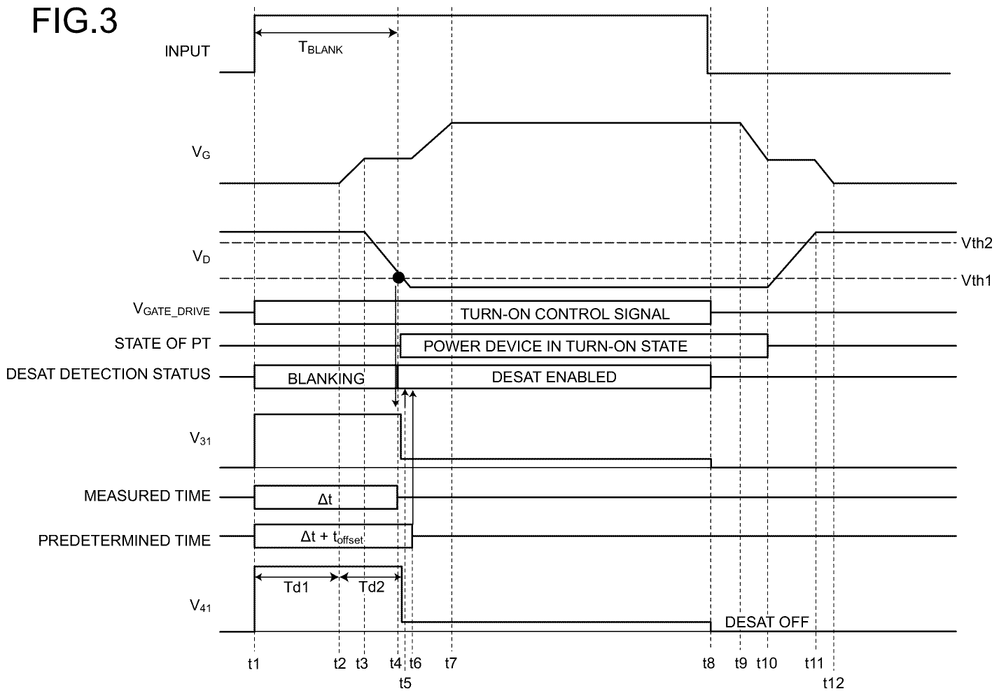

One end of the voltage source 32 is connected to the input node 31b of the comparison circuit 31, and the other end of the voltage source 32 is connected to the ground potential. The voltage source 32 may be a constant voltage source, and generates a reference voltage corresponding to a threshold voltage Vth1. The threshold voltage Vth1 corresponds to a fall in a waveform of a voltage V_{D} at the one end D of the power device PT (see FIG. 3).

For example, the comparison circuit 31 compares a voltage V_{VDDET} of the terminal VDDET with the threshold voltage Vth1.

In a case where the input node 31a is a non-inverting input node and the input node 31b is an inverting input node, the comparison circuit 31 outputs a comparison result at an H level when the voltage V_{VDDET} is higher than the threshold voltage Vth1, and outputs a comparison result at an L level when the voltage V_{VDDET} is lower than the threshold voltage Vth1.

In a case where the input node 31a is an inverting input node and the input node 31b is a non-inverting input node, the comparison circuit 31 outputs a comparison result at an L level when the voltage V_{VDDET} is higher than the threshold voltage Vth1, and outputs a comparison result at an H level when the voltage V_{VDDET} is lower than the threshold voltage Vth1.

One end of the current source 33 is connected to a power supply potential, and the other end of the current source 33 connected to a node between the input node 31a of the comparison circuit 31 and the terminal VDDET. The current source 33 may be a constant current source, and can supply a constant current to the capacitive element 34. The constant current supplied by the current source 33 can be determined in advance according to an operation characteristic required for the detection circuit 3. The constant current supplied by the current source 33 can be determined in advance according to a charging characteristic of the capacitive element 34 required for detecting a fall in a voltage at the one end D of the power device PT.

One end of the capacitive element 34 is connected to a node between the input node 31a of the comparison circuit 31 and the terminal VDDET, and the other end of the capacitive element 34 is connected to the ground potential. The capacitance value of the capacitive element 34 can be determined in advance according to an operation characteristic required for the detection circuit 3. The capacitance value of the capacitive element 34 can be determined in advance according to a charging characteristic of the capacitive element 34 required for detecting a fall in a voltage at the one end D of the power device PT.

The switch 35 is connected between one end of the capacitive element 34 and the ground potential. One end of the switch 35 is connected to a node between the input node 31a of the comparison circuit 31 and the terminal VDDET, the other end of the switch 35 is connected to the ground potential, and the control terminal of the switch 35 is connected to the control unit 36.

When receiving a control signal MASK1 at a non-active level (e.g., L level) from the control unit 36, the switch 35 is turned off to disconnect one end of the capacitive element 34 from the ground potential and make the capacitive element 34 chargeable. When receiving a control signal MASK1 at an active level (e.g., an H level) from the control unit 36, the switch 35 is turned on to connect one end of the capacitive element 34 to the ground potential, draw charges from one end of the capacitive element 34, set the input node 31a of the comparison circuit 31 to the ground potential, and disable the function of the detection circuit.

An input node 36a of the control unit 36 is connected to the terminal INPUT, an input node 36b of the control unit 36 is connected to the comparison circuit 31, an output node 36d of the control unit 36 is connected to the switch 35, and an output node 36e of the control unit 36 is connected to the protection circuit 4.

The control unit 36 generates a control signal MASK in response to the input signal INPUT and supplies the control signal MASK to the switch 35.

As the comparison result of the comparison circuit 31 is inverted, the control unit 36 generates a control signal EN_DESAT for enabling the protection circuit 4, and supplies the control signal EN_DESAT to the protection circuit 4.

In a case where the input node 31a of the comparison circuit 31 is a non-inverting input node and the input node 31b of the comparison circuit 31 is an inverting input node, the control unit 36 supplies a control signal EN_DESAT at a non-active level to the protection circuit 4 in a period TP1 in which the comparison circuit 31 outputs a comparison result at an H level. The control unit 36 supplies a control signal EN_DESAT at an active level to the protection circuit 4 in a period TP2 in which the comparison circuit 31 outputs a comparison result at an L level.

In a case where the input node 31a of the comparison circuit 31 is an inverting input node and the input node 31b of the comparison circuit 31 is a non-inverting input node, the control unit 36 supplies a control signal EN_DESAT at a non-active level to the protection circuit 4 in a period TP11 in which the comparison circuit 31 outputs a comparison result at an L level. The control unit 36 supplies a control signal EN_DESAT at an active level to the protection circuit 4 in a period TP12 in which the comparison circuit 31 outputs a comparison result at an H level.

The protection circuit 4 is connected between the terminal INPUT, the detection circuit 3, the drive circuit 5, and the terminal DESAT. The protection circuit 4 can detect DESAT of the power device PT via the terminal DESAT. When detecting the DESAT of the power device PT, the protection circuit 4 supplies a signal OFF_CTR for an instruction to shut down the power device PT to the drive circuit 5.

The protection circuit 4 includes a comparison circuit 41, a voltage source 42, a current source 43, a switch 45, a filter 47, and a control unit (signal generation circuit) 46.

The comparison circuit 41 has an input node 41a, an input node 41b, and an output node 41c. The input node 41a is connected to the one end D of the power device PT via the terminal DESAT, the resistive element R_{DESAT}, and the rectifier element D_{DESAT}. The input node 41b is connected to the voltage source 42. The output node 41c is connected to the control unit 46 via the filter 47.

The filter 47 is connected between the comparison circuit 41 and the control unit 46. The filter 47 rejects a short pulse signal when the comparison result of the comparison circuit 41 is an erroneous determination, and supplies the rejected signal to the control unit 46.

One end of the voltage source 42 is connected to the input node 41b of the comparison circuit 41, and the other end of the voltage source 42 is connected to the ground potential. The voltage source 42 may be a constant voltage source, and generates a reference voltage corresponding to a threshold voltage Vth2. The threshold voltage Vth2 corresponds to a rise in a waveform of a voltage V_{D} at the one end D of the power device PT (see FIG. 3).

For example, the comparison circuit 41 compares a voltage V_{DESAT} of the terminal DESAT with the threshold voltage Vth2.

In a case where the input node 41a is a non-inverting input node and the input node 41b is an inverting input node, the comparison circuit 41 outputs a comparison result at an H level when the voltage V_{DESAT} is higher than the threshold voltage Vth2, and outputs a comparison result at an L level when the voltage V_{DESAT} is lower than the threshold voltage Vth2.

In a case where the input node 41a is an inverting input node and the input node 41b is a non-inverting input node, the comparison circuit 41 outputs a comparison result at an L level when the voltage V_{DESAT} is higher than the threshold voltage Vth2, and outputs a comparison result at an H level when the voltage V_{DESAT} is lower than the threshold voltage Vth2.

One end of the current source 43 is connected to the power supply potential, and the other end of the current source 43 connected to a node between the input node 41a of the comparison circuit 41 and the terminal DESAT. The current source 43 may be a constant current source, and can supply a constant current to the capacitive element C_{DESAT} via the terminal DESAT. The constant current supplied by the current source 43 can be determined in advance according to an operation characteristic required for the protection circuit 4. The constant current supplied by the current source 43 can be determined in advance according to a charging characteristic of the capacitive element C_{DESAT} required for the DESAT detection of the power device PT.

The switch 45 is connected between one end of the capacitive element C_{DESAT} and the ground potential. One end of the switch 45 is connected to a node between the input node 41a of the comparison circuit 41 and the terminal DESAT, the other end of the switch 45 is connected to the ground potential, and the control terminal of the switch 45 is connected to the control unit 46.

When receiving a control signal MASK2 at a non-active level (e.g., L level) from the control unit 46, the switch 45 is turned off to disconnect one end of the capacitive element 34 from the ground potential and make the capacitive element 34 chargeable. When receiving a control signal MASK2 at an active level (e.g., H level) from the control unit 46, the switch 45 is turned on to connect one end of the capacitive element 34 to the ground potential, draws charges from one end of the capacitive element 34K, and discharges the capacitive element to the ground potential.

An input node 46a of the control unit 46 is connected to the terminal INPUT, an input node 46b of the control unit 46 is connected to the comparison circuit 41 via the filter 47, a control node 46c of the control unit 46 is connected to the detection circuit 3, an output node 46d of the control unit 46 is connected to the switch 45, and an output node 46e of the control unit 46 is connected to the drive circuit 5.

As the comparison result of the comparison circuit 41 is inverted, the control unit 46 generates a control signal OFF_CTR for an instruction to shut down the power device PT and supplies the control signal OFF_CTR to the drive circuit 5.

In a case where the input node 41a of the comparison circuit 41 is a non-inverting input node and the input node 41b of the comparison circuit 41 is an inverting input node, the control unit 46 supplies a control signal OFF_CTR at an active level to the drive circuit 5 in a period TP21 in which the comparison circuit 41 outputs a comparison result at an H level. The control unit 46 supplies a control signal OFF_CTR at a non-active level to the drive circuit 5 in a period TP22 in which the comparison circuit 41 outputs a comparison result at an L level.

In a case where the input node 41a of the comparison circuit 41 is an inverting input node and the input node 41b of the comparison circuit 41 is a non-inverting input node, the control unit 46 supplies a control signal OFF_CTR at an active level to the drive circuit 5 in the period TP11 in which the comparison circuit 41 outputs a comparison result at an L level. The control unit 46 supplies a control signal OFF_CTR at a non-active level to the drive circuit 5 in the period TP12 in which the comparison circuit 41 outputs a comparison result at an H level.

The drive circuit 5 includes an input node 5a, an output node 5b, and a control node 5c. The input node 5a is connected to the terminal INPUT. The output node 5b is connected to the control terminal G of the power transistor PT. The control node 5c is connected to the protection circuit 4.

While receiving a control signal Shutdown at a non-active level, the drive circuit 5 generates a drive signal DRV for switching the power transistor PT in response to an input signal IN, and supplies the drive signal DRV to the control terminal G of the power transistor PT. As a result, the power transistor PT can be subjected to switching control.

When receiving a control signal Shutdown at an active level, the drive circuit 5 generates a drive signal DRV for maintaining the power transistor PT in a turn-off state regardless of the input signal IN, and supplies the drive signal DRV to the control terminal G of the power transistor PT. As a result, the power transistor PT is maintained in the turn-off state. As a result, the power transistor PT can be protected from an overcurrent generated in the load LD.

In the semiconductor device 1 illustrated in FIG. 1, the DESAT detection is performed in a period from timing t4 to timing t8 as illustrated in FIG. 3. FIG. 3 is a waveform diagram illustrating an operation of the semiconductor device 1.

In the period from timing t4 to timing t8, the protection circuit 4 is enabled, and the DESAT detection by the protection circuit 4 is enabled. The DESAT detection period (t4 to t8) is a period from timing t4 to timing t10 when the power device PT is in a turn-on state.

In the DESAT detection, as an excessive current flows into the power device PT in the turn-on state, the protection circuit 4 detects a rise in the voltage V_{D} at the one end D of the power device PT exceeding the threshold voltage Vth2. FIG. 3 exemplifies a case where the voltage V_{D} is maintained to be lower than the threshold voltage Vth2 in the period from timing t4 to timing t8, and a rise in the voltage V_{D} exceeding the threshold voltage Vth2 is not detected.

Note that, although not illustrated, in a case where a rise in the voltage V_{D} exceeding the threshold voltage Vth2 is detected, the protection circuit 4 transitions the control signal OFF_CTR to an active level and supplies the control signal OFF_CTR to the drive circuit 5 accordingly. Accordingly, the drive circuit 5 transitions a drive signal V_{GATE_DRIVE} to a non-active level (e.g., an L level), and the power device PT is turned off. As a result, the power device PT is controlled to be turned off.

The start timing of “DESAT enabled” at which DESAT detection becomes possible is determined using timing t1, when the input signal INPUT becomes an active level (e.g., an H level), and accordingly, the drive signal V_{GATE_DRIVE} of the power device PT becomes an active level (e.g., an H level), as a trigger. A period from timing t1 to timing t8 when the drive signal V_{GATE_DRIVE} is maintained at the active level is expressed as a “turn-on control signal”.

At this time, as illustrated in FIG. 3, there are a delay time Td1 corresponding to a dead time from when the drive signal V_{GATE_DRIVE} becomes the active level to when the voltage V_{G} of the control terminal G starts to rise, and a delay time Td2 corresponding to a switching time from when the voltage V_{G} starts to rise to when the power device PT transitions to the turn-on state.

Here, it is conceivable to measure a dead time and a switching time in advance, and experimentally determine a blanking time T_{BLANK} in advance as a delay time (=dead time+switching time) from the trigger timing t1 to the start timing of “DESAT enabled”, so that the blanking time T_{BLANK} is fixedly set in the protection circuit 4.

For example, in the protection circuit 4, a predetermined value corresponding to the blanking time T_{BLANK} may be set in advance in the timer 461 of the control unit 46. In this case, immediately before timing t1, the protection circuit 4 sets the count value of the timer 461 to an initial value and sets the control signal MASK2 to an active level. When detecting a rise in a waveform of the input signal INPUT, the protection circuit 4 starts a counting operation of the timer 461. When the count value reaches a predetermined value, the protection circuit 4 sets the control signal MASK2 to a non-active level, turns off the switch 45, and enables DESAT detection.

However, among the dead time and the switching time, at least the switching time tends to vary due to manufacturing variations of the power device PT, influence of environmental temperature, and the like.

When the fixedly set blanking time T_{BLANK} is longer than the actual “dead time+switching time”, the DESAT cannot be detected in a period from when the power device PT transitions to the turn-on state until the blanking time T_{BLANK} elapses. If an excessive current flows into the power device PT in the turn-on state during this period, the power device PT may be damaged. That is, it may be difficult to appropriately detect DESAT.

When the fixedly set blanking time T_{BLANK} is shorter than the actual “dead time+switching time”, the blanking time T_{BLANK} elapses although the power device PT is in the turn-on state, which may result in erroneous detection of DESAT. During this period, even though an excessive current does not flow into the power device PT, if the voltage V_{D} at the one end D exceeds the threshold voltage Vth because the power device PT is in the turn-off state, it may be erroneously detected that DESAT has occurred. That is, it may be difficult to appropriately detect DESAT.

Therefore, in the semiconductor device 1, the detection circuit 3 detects a fall in the voltage V_{D} at the one end D of the power device PT, and the protection circuit 4 is enabled to detect DESAT according to the detection timing, thereby being able to optimize the start timing of the enablement of DESAT.

For example, immediately before timing t1, the detection circuit 3 sets the control signal MASK1 to an active level and maintains the switch 35 in the turn-on state. As a result, the detection circuit 3 is disabled from detecting a fall in a waveform. The detection circuit 3 sets the control signal EN_DESAT to a non-active level. The protection circuit 4 sets the control signal MASK2 to an active level and maintains the switch 45 in the turn-on state. As a result, the protection circuit 4 is disabled from detecting DESAT.

When detecting a rise in a waveform of the input signal INPUT at timing t1, the drive circuit 5 sets the drive signal V_{GATE_DRIVE} to an active level.

In addition, when detecting a rise in a waveform of the input signal INPUT, the detection circuit 3 sets the control signal MASK1 to a non-active level and turns off the switch 35. Accordingly, the detection circuit 3 is enabled to detect a fall in a waveform of the voltage V_{D} at the one end D of the power device PT. That is, the detection circuit 3 becomes capable of detecting a fall in a waveform of the voltage V_{D}.

At this time, the power device PT is turned off, and the voltage V_{D} at the one end D is maintained at a predetermined level (e.g., an H level). Accordingly, the rectifier element D_{DET} is cut off, the current of the current source 33 charges the capacitive element 34, the voltage of the terminal VDDET is higher than the threshold voltage Vth1, and the comparison result V₃₁ of the comparison circuit 31 becomes an H level. Until a control signal EN_DESAT at an active level comes from the detection circuit 3, the protection circuit 4 sets the control signal MASK2 to an active level and maintains the switch 45 in the turn-on state, so that the voltage of the terminal DESAT is lower than the threshold voltage Vth2 and the comparison result V₄₁ of the comparison circuit 41 is at the L level.

At timing t2, the voltage V_{G} of the control terminal G starts to rise and the power device PT starts to be turned on accordingly, and at timing t3, the voltage V_{D} at the one end D starts to fall.

At timing t4, when the voltage V_{D} at the one end D falls below the threshold voltage Vth1, the comparison result V₃₁ of the comparison circuit 31 is inverted. That is, the detection circuit 3 detects a fall in a waveform of the voltage V_{D} at the one end D. Accordingly, the detection circuit 3 sets the control signal EN_DESAT to an active level and supplies the control signal EN_DESAT to the protection circuit 4.

In response to the control signal EN_DESAT at the active level, the protection circuit 4 sets the control signal MASK2 to a non-active level and turns off the switch 45. Accordingly, the protection circuit 4 is enabled to detect DESAT. That is, the protection circuit 4 becomes capable of detecting the DESAT of the power device PT. In FIG. 3, the blanking period from timing t1 to timing t4 is expressed as “blanking”.

At timing t5 immediately thereafter, the transition of the power device PT to the turn-on state is completed.

At timing t7, the voltage V_{G} of the control terminal G reaches a predetermined level (e.g., an H level) and is maintained at the predetermined level.

When detecting a fall in a waveform of the input signal INPUT at timing t8, the drive circuit 5 sets the drive signal V_{GATE_DRIVE} to a non-active level. In FIG. 3, the period from timing t1 to timing t8 when the drive signal V_{GATE_DRIVE} is maintained at the active level is expressed as a “turn-on control signal”.

In addition, when detecting a fall in a waveform of the input signal INPUT, the detection circuit 3 sets the control signal MASK1 to an active level and turns on the switch 35. As a result, the detection circuit 3 is disabled again from detecting a fall in a waveform. The detection circuit 3 sets the control signal EN_DESAT to a non-active level and supplies the control signal EN_DESAT to the protection circuit 4. The protection circuit 4 sets the control signal MASK2 to an active level and turns on the switch 45. As a result, the protection circuit 4 is disabled again from detecting DESAT. In FIG. 3, the period from timing t4 to timing t8 when the DESAT detection is enabled is expressed as “DESAT enabled”.

At timing t9, the voltage V_{G} of the control terminal G starts to fall, and accordingly, at timing t10 immediately thereafter, the power device PT starts to be turned off, and the voltage V_{D} at the one end D starts to rise. In FIG. 3, a period from timing t5 to timing t10 when the power device PT is maintained in the turn-on state is expressed as a “power device in turn-on state”.

At timing t11, the voltage V_{D} at the one end D reaches a predetermined level (e.g., an H level) and is maintained at the predetermined level.

At timing t12 thereafter, the voltage V_{G} of the control terminal G falls to the reference level (e.g., an L level), and the transition of the power device PT to the turn-off state is completed.

As illustrated in FIG. 3, the timing at which the power device PT transitions to the turn-on state is determined from the result of detecting the fall in the waveform of the voltage V_{D} at the one end D of the power device PT, and is set as the timing at which DESAT detection is enabled. As a result, it is possible to end the blanking time and start the enablement of DESAT detection at a timing close to the completion of the transition of the power device PT to the turn-on state, without being affected by the manufacturing variations or the dependence on temperature of the power device PT.

As described above, in the embodiment, in the semiconductor device 1, the detection circuit 3 detects a fall in the voltage V_{D} at the one end D of the power device PT, and the protection circuit 4 is enabled to detect DESAT according to the detection timing. As a result, it is possible to optimize the start timing of the enablement of DESAT. In addition, needs to design a margin for the timing at which DESAT detection is enabled in the system may be suppressed. This makes it possible to reducing loads in designing the system design, and enables the system design to be QTAT.

In the detection circuit 3 illustrated in FIG. 1, the capacitive element 34 may be omitted. In this case, the current source 33 charges the current to the parasitic capacitance of the line connecting the comparison circuit 31 and the terminal VDDET.

In the semiconductor device 1 illustrated in FIG. 1, the capacitive element C_{DESAT} may be omitted. In this case, the current source 43 of the protection circuit 4 charges the current to the parasitic capacitance of the line connecting the comparison circuit 41 and the terminal DESAT.

The control unit 46 of the protection circuit 4 illustrated in FIG. 1 sets the control signal MASK2 to an active level in response to a control signal EN_DESAT received from the detection circuit 3 without using the timer 461. Therefore, in the control unit 46, the timer 461 may be omitted.

### First Modification of Embodiment

In a case where DESAT detection is enabled by detecting a fall in the voltage V_{D} at the one end D of the power device PT, the voltage V_{D} at the one end D may not fall while the power device PT is controlled to be turned on depending on the timing of a defect or failure of the load (e.g., an inverter device) LD. For this reason, a history of the time at which a fall in the voltage V_{D} at the one end D is detected may be kept to enable DESAT detection based on the past time history.

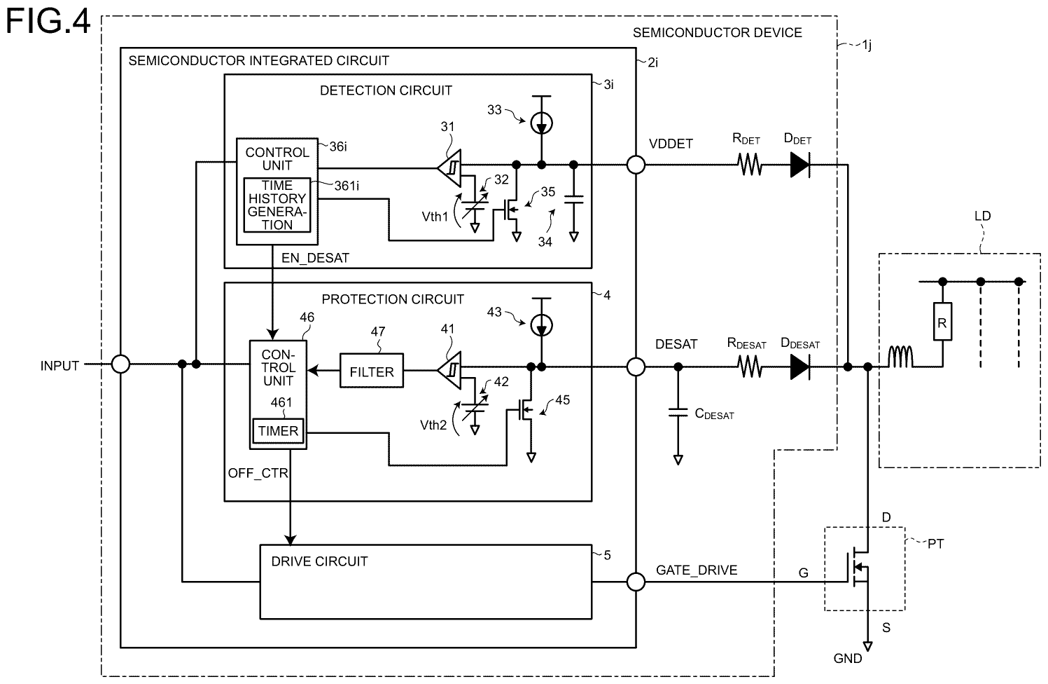

In a semiconductor device 1i, as illustrated in FIG. 4, a detection circuit 3i of a semiconductor integrated circuit 2i may include a control unit 36i instead of the control unit 36 (see FIG. 1). FIG. 4 is a diagram illustrating a configuration of the semiconductor device 1i according to a first modification of the embodiment. The control unit 36i includes a time history generation unit 361i.

In the control unit 36i, the time history generation unit 361i measures the time from the rise in the waveform of the input signal INPUT until the comparison result V₃₁ of the comparison circuit 31 is inverted, and holds the measured time Δt. As a predetermined time corresponding to the measured time Δt (see FIG. 3) from the rise in the waveform of the input signal INPUT elapses, the time history generation unit 361i generates a control signal EN_DESAT for enabling the protection circuit 4 and supplies the control signal EN_DESAT to the protection circuit 4. The predetermined time may be a time obtained by adding an offset time t_{offset} to the history time Δt. Any time greater than 0 may be used as the offset time t_{offset}.

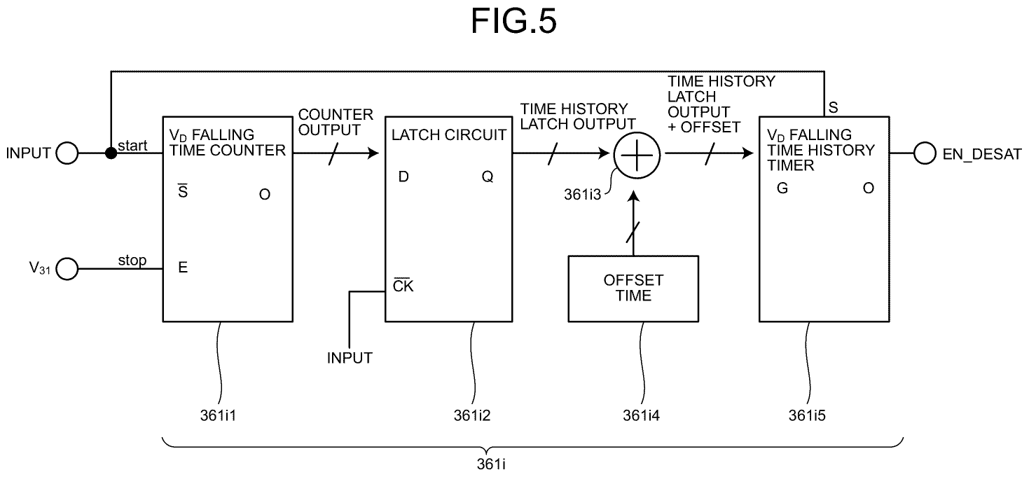

The time history generation unit 361i may be configured as illustrated in FIG. 5. FIG. 5 is a circuit diagram illustrating a configuration of the time history generation unit 361i in the first modification of the embodiment.

The time history generation unit 361i includes a counter 361i1, a latch circuit 361i2, an adder 361i3, a setting circuit 361i4, and a timer 361i5.

In the counter 361i1, a node S⁻ is connected to the terminal INPUT and the node S⁻ of the counter 361i1, a node E is connected to the comparison circuit 31, and a node O is connected to a node D of the latch circuit 36ii2. The counter 361i1 counts a falling time for the voltage V_{D} at the one end D. The falling time for the voltage V_{D} at the one end D is a time from the transition from the L level to the H level of the input signal INPUT to the timing at which the fall in the voltage V_{D} is detected at the one end. That is, the counter 361i1 starts the counting operation as the input signal INPUT received at the node S⁻ rises, and ends the counting operation as the comparison result V₃₁ of the comparison circuit 31 received at the node E is inverted. The counter 361i1 outputs a count value to the latch circuit 361i2. The count value indicates a time Δt measured by the counter 361i1.

In the latch circuit 361i2, a node CK is connected to the terminal INPUT, and a node Q is connected to the adder 361i3. The falling time for the voltage V_{D} at one end counted by the counter 361i1 is held by the latch circuit 361i2 at a timing when the input signal INPUT transitions from the H level to the L level. That is, as the input signal INPUT received at the node CK falls, the latch circuit 361i2 latches the count value of the counter 361i1, and outputs the latched value from the node Q to the adder 361i3.

In the setting circuit 361i4, an output node is connected to the adder 361i3. In the setting circuit 361i4, the offset time t_{offset} is set in advance. The setting circuit 361i4 outputs a value indicating the offset time t_{offset} to the adder 361i3.

In the adder 361i3, a first input node is connected to the latch circuit 361i2, a second input node is connected to the setting circuit 361i4, and an output node is connected to a node E of the timer 361i5. The adder 361i3 adds the latched value (that is, a value indicating the measured time Δt) and the value indicating the offset time t_{offset}, and outputs a value of an addition result to the timer 361i5. The value of the addition result indicates a predetermined time Δt+t_{offset}.

In the timer 361i5, a node O is connected to the protection circuit 4. The timer 361i5 receives the value of the addition result at a node G. In a reset state, the timer 361i5 outputs a control signal EN_DESAT at a non-active level from the node O to the protection circuit 4. The timer 361i5 starts counting as the input signal INPUT received at a node S rises. When the count value reaches the value of the addition result received at the node G, the timer 361i5 ends the counting operation, transitions the control signal EN_DESAT to an active level, and supplies the control signal EN_DESAT to the protection circuit 4.

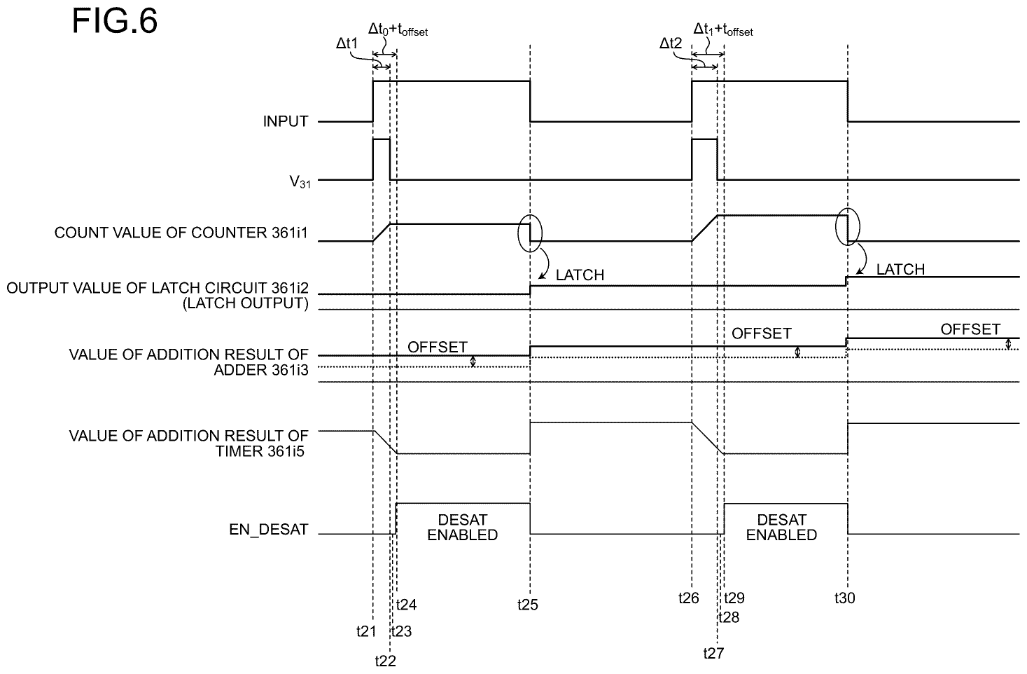

For example, the time history generation unit 361i may operate as illustrated in FIG. 6. FIG. 6 is a waveform diagram illustrating an operation of the time history generation unit 361i in the first modification of the embodiment.

At timing t21, the counter 361i1 of the time history generation unit 361i starts an operation of counting the time Δt as the input signal INPUT rises. The timer 361i5 starts an operation of counting the predetermined time (Δt₀+t_{offset}) as the input signal INPUT rises. Δt₀ is a time previously measured as Δt. The comparison circuit 31 starts to output a comparison result V₃₁ at an H level.

At timing t22, as the comparison result V₃₁ of the comparison circuit 31 is inverted from the H level to the L level, the counter 361i1 ends the operation of counting the time Δt, and outputs a count value of a measured time Δt=Δt₁ to the latch circuit 361i2.

At timing t23 when the predetermined time (Δt₀+t_{offset}) has elapsed from timing t21, the count value of the timer 361i5 reaches a value corresponding to the predetermined time (Δt₀+t_{offset}).

At timing t24 immediately thereafter, the timer 361i5 sets the control signal EN_DESAT to an active level and supplies the control signal EN_DESAT to the protection circuit 4. Accordingly, in the protection circuit 4, DESAT is enabled.

At timing t25, as the input signal INPUT falls, the latch circuit 361i2 latches the count value of the counter 361i1, and starts to output the latched value to the adder 361i3. Accordingly, the adder 361i3 starts to output a value obtained by adding an offset to the latched value. A value of an addition result of the adder 361i3 is output to the timer 361i5 and set as a value to be counted by the timer 361i5.

As the input signal INPUT falls, the timer 361i5 sets the control signal EN_DESAT to a non-active level and supplies the control signal EN_DESAT to the protection circuit 4. Accordingly, in the protection circuit 4, DESAT is disabled.

At timing t26, the counter 361i1 of the time history generation unit 361i starts an operation of counting the time Δt as the input signal INPUT rises. The timer 361i5 starts an operation of counting the predetermined time (Δt₁+t_{offset}) as the input signal INPUT rises. Δt₁ is a time previously measured as Δt. The comparison circuit 31 starts to output a comparison result V₃₁ at an H level.

At timing t27, as the comparison result V₃₁ of the comparison circuit 31 is inverted from the H level to the L level, the counter 361i1 ends the operation of counting the time Δt, and outputs a count value of a measured time Δt=Δt₂ to the latch circuit 361i2.

At timing t28 when the predetermined time (Δt₁+t_{offset}) has elapsed from timing t26, the count value of the timer 361i5 reaches a value corresponding to the predetermined time (Δt₁+t_{offset}).

At timing t29 immediately thereafter, the timer 361i5 sets the control signal EN_DESAT to an active level and supplies the control signal EN_DESAT to the protection circuit 4. Accordingly, in the protection circuit 4, DESAT is enabled.

At timing t30, as the input signal INPUT falls, the latch circuit 361i2 latches the count value of the counter 361i1, and starts to output the latched value to the adder 361i3. Accordingly, the adder 361i3 starts to output a value obtained by adding an offset to the latched value. A value of an addition result of the adder 361i3 is output to the timer 361i5 and set as a value to be counted by the timer 361i5.

As the input signal INPUT falls, the timer 361i5 sets the control signal EN_DESAT to a non-active level and supplies the control signal EN_DESAT to the protection circuit 4. Accordingly, in the protection circuit 4, DESAT is disabled.

In this manner, in the semiconductor device 1i, the detection circuit 3i keeps a history of the time at which a fall in the voltage V_{D} at the one end D is detected, and enables DESAT detection based on the past time history. For example, the detection circuit 4 is enabled to detect DESAT by using a predetermined time obtained by adding an offset t_{offset} to the time Δt measured immediately before in consideration of variations. This also makes it possible to optimize the start timing of the enablement of DESAT.

### Second Modification of Embodiment

Alternatively, the operation in the embodiment and the operation in the first modification may be combined with respect to the start timing of “DESAT enabled” at which DESAT detection becomes possible. For example, the start timing of the “DESAT enabled” may correspond to the earlier one of the timing at which the voltage V_{D} falls at the one end D of the power transistor PT and the timing at which the predetermined time (Δt+t_{offset}) has elapsed from the rise in the waveform of the input signal INPUT.

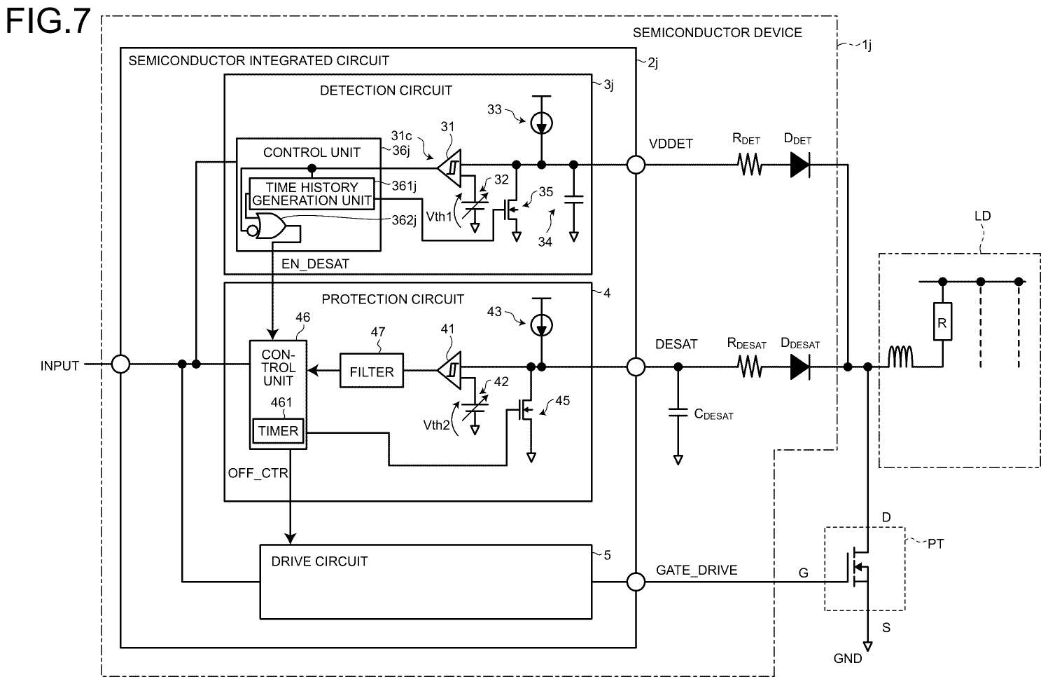

At this time, in a semiconductor device 1j, as illustrated in FIG. 7, a detection circuit 3j of a semiconductor integrated circuit 2j may include a control unit 36j instead of the control unit 36i (see FIG. 4). FIG. 7 is a diagram illustrating a configuration of the semiconductor device 1j according to a second modification of the embodiment.

The control unit 36j generates a control signal EN_DESAT for enabling the protection circuit 4 as the comparison result V₃₁ of the comparison circuit 31 is inverted or as the predetermined time (Δt+t_{offset}) has elapsed from the rise in the waveform of the input signal INPUT. For example, the control unit 36j may generate a control signal EN_DESAT for enabling the protection circuit 4 according to the earlier one of the timing at which the comparison result V₃₁ of the comparison circuit 31 is inverted and the timing at which the predetermined time (Δt+t_{offset}) has elapsed from the rise in the waveform of the input signal INPUT.

The control unit 36j may further include an operator 362j. In the operator 362j, a first input node is connected to the output node 31c of the comparison circuit 31, a logic inversion of a second input node is connected to the output node of the time history generation unit 361i, and an output node is connected to the protection circuit 4.

The logical sum operator 362j calculates a logical sum of the logical inversion of the comparison result V₃₁ of the comparison circuit 31 and the control signal EN_DESAT (see FIG. 5) output from the time history generation unit 361i, and generates a control signal EN_DESAT as a calculation result. The control signal-EN_DESAT transitions from the non-active level to the active level at the earlier one of the timing at which the voltage V_{D} falls at the one end D of the power transistor PT and the predetermined time (Δt+t_{offset}) obtained by the time history generation unit 361i. As a result, the start timing of the “DESAT enabled” can be set to the earlier one of the timing at which the voltage V_{D} falls at the one end D of the power transistor PT and the predetermined time (Δt+t_{offset}) obtained by the time history generation unit 361i.

In this manner, in the semiconductor device 1j, the detection circuit 3j generates a control signal EN_DESAT for enabling the protection circuit 4 as the comparison result V₃₁ of the comparison circuit 31 is inverted or as the predetermined time (Δt+t_{offset}) has elapsed from the rise in the waveform of the input signal INPUT. This also makes it possible to optimize the start timing of the enablement of DESAT.

### Third Modification of Embodiment

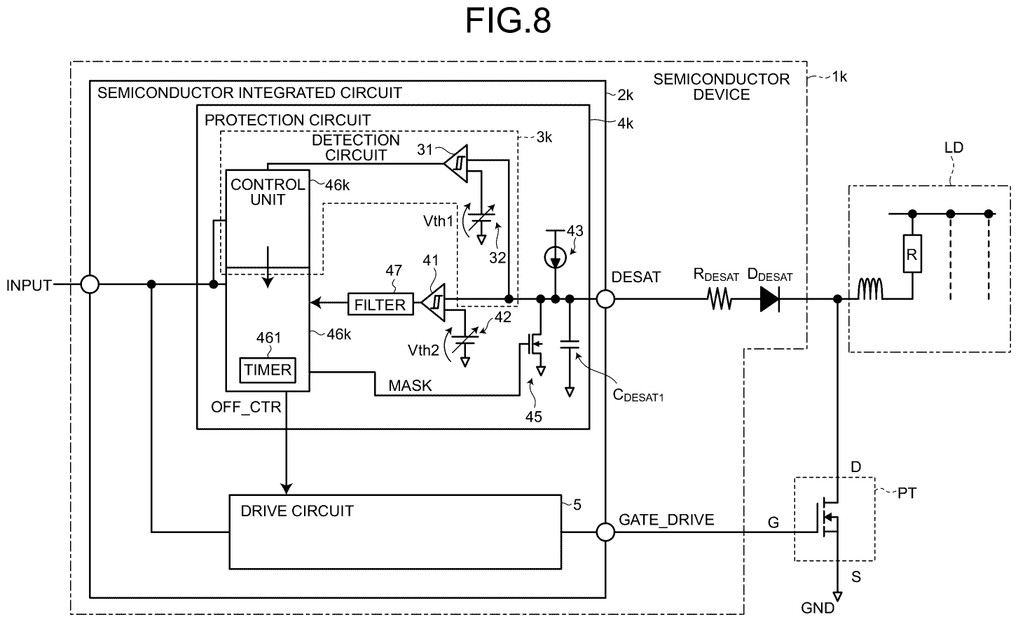

A configuration of a semiconductor device 1k may be simplified as illustrated in FIG. 8. FIG. 8 is a diagram illustrating the configuration of the semiconductor device 1k according to a third modification of the embodiment.

In a semiconductor integrated circuit 2k of the semiconductor device 1k, the detection circuit 3 and the protection circuit 4 (see FIG. 1) are merged to form a protection circuit 4k including a detection circuit 3k. In the detection circuit 3k, the current source 33, the capacitive element 34, the switch 35, and the control unit 36 are omitted. The protection circuit 4k includes a control unit 46k instead of the control unit 46 (see FIG. 1).

The function of the control unit 36 is added to the control unit 46k. As the comparison result of the comparison circuit 31 is inverted, the control unit 46k enables the protection circuit 4k and enables DESAT detection by the protection circuit 4k.

In addition, in the semiconductor device 1k, the capacitive element C_{DESAT} (see FIG. 1) is omitted, and instead, a capacitive element C_{DESAT1} is added to the protection circuit 4k. The capacitance value of the capacitive element C_{DESAT1} can be determined in advance according to a charging characteristic of the capacitive element C_{DESAT1} required for detecting a fall in a voltage at the one end D of the power device PT.

In this manner, in the semiconductor integrated circuit 2k of the semiconductor device 1k, configuration is simplified by configuring the protection circuit 4k including the detection circuit 3k. As a result, the circuit scale of the semiconductor integrated circuit 2k can be reduced, thereby being able to save the space of the semiconductor device 1k and reducing the cost of the semiconductor device 1k.

In the configuration illustrated in FIG. 8, the capacitive element C_{DESAT1} may be omitted. In this case, the current source 43 of the protection circuit 4k charges the current to the parasitic capacitance of the line connecting the comparison circuit 41 and the terminal DESAT.

### Fourth Modification of Embodiment

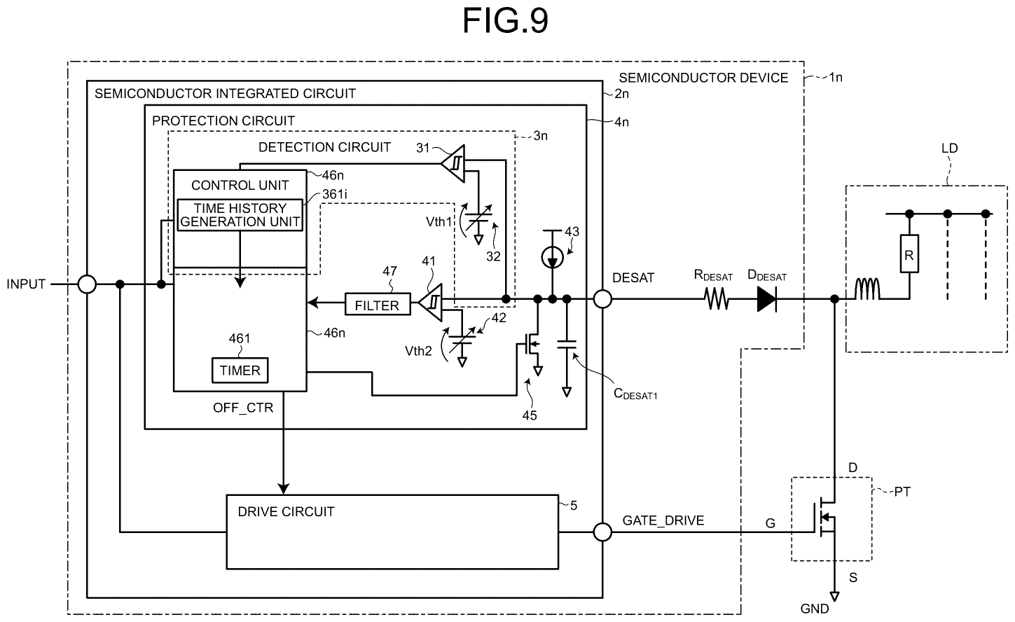

A configuration of a semiconductor device 1n may be simplified as illustrated in FIG. 9. FIG. 9 is a diagram illustrating the configuration of the semiconductor device 1n according to a fourth modification of the embodiment.

In a semiconductor integrated circuit 2n of the semiconductor device 1n, the detection circuit 3i and the protection circuit 4 (see FIG. 4) are merged to form a protection circuit 4n including a detection circuit 3n. In the detection circuit 3n, the current source 33, the capacitive element 34, the switch 35, and the control unit 36i are omitted. The protection circuit 4n includes a control unit 46n instead of the control unit 46i (see FIG. 4).

The function of the control unit 36i is added to the control unit 46n. As the predetermined time (Δt+t_{offset}) has elapsed from the rise in the waveform of the input signal INPUT, the control unit 46n enables the protection circuit 4n and enables DESAT detection by the protection circuit 4n. For example, the control unit 46n enables the DESAT detection as the predetermined time (Δt+t_{offset}) has elapsed from the rise in the waveform of the input signal INPUT. As a result, the protection circuit 4n becomes capable of detecting the DESAT of the power transistor PT.

In addition, in the semiconductor device 1n, the capacitive element C_{DESAT} (see FIG. 1) is omitted, and instead, a capacitive element C_{DESAT1} is added to the protection circuit 4k. The capacitance value of the capacitive element C_{DESAT1} can be determined in advance according to a charging characteristic of the capacitive element C_{DESAT1} required for detecting a fall in a voltage at the one end D of the power device PT.

In this manner, in the semiconductor integrated circuit 2n of the semiconductor device 1n, configuration is simplified by configuring the protection circuit 4n including the detection circuit 3n. As a result, the circuit scale of the semiconductor integrated circuit 2n can be reduced, thereby being able to save the space of the semiconductor device 1n and reducing the cost of the semiconductor device 1n.

In the configuration illustrated in FIG. 9, the capacitive element C_{DESAT1} may be omitted. In this case, the current source 43 of the protection circuit 4n charges the current to the parasitic capacitance of the line connecting the comparison circuit 41 and the terminal DESAT.

### Fifth Modification of Embodiment

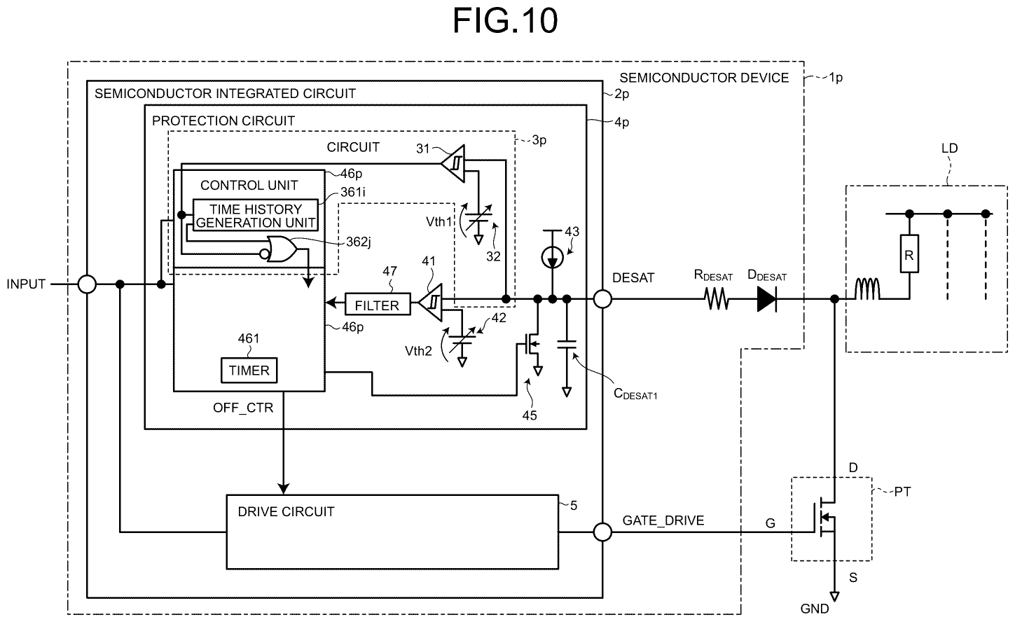

A configuration of a semiconductor device 1p may be simplified as illustrated in FIG. 10. FIG. 10 is a diagram illustrating the configuration of the semiconductor device 1p according to a fifth modification of the embodiment.

In a semiconductor integrated circuit 2p of the semiconductor device 1p, the detection circuit 3j and the protection circuit 4 (see FIG. 7) are merged to form a protection circuit 4p including a detection circuit 3p. In the detection circuit 3p, the current source 33, the capacitive element 34, the switch 35, and the control unit 36j are omitted. The protection circuit 4p includes a control unit 46p instead of the control unit 46j (see FIG. 7).

The function of the control unit 36j is added to the control unit 46p. The control unit 46p enables the protection circuit 4p and enables DESAT detection by the protection circuit 4p as the comparison result of the comparison circuit 31 is inverted or as the predetermined time (Δt+t_{offset}) has elapsed from the rise in the waveform of the input signal INPUT. For example, as the predetermined time (Δt+t_{offset}) has elapsed from the rise in the waveform of the input signal INPUT, for example, the control unit 46p can enable DESAT detection with the start timing of “DESAT enabled” being the earlier one of the timing at which the voltage V_{D} falls at the one end D of the power transistor PT and the predetermined time (Δt+t_{offset}) obtained by the time history generation unit 361i. As a result, the protection circuit 4p becomes capable of detecting the DESAT of the power transistor PT.

In addition, in the semiconductor device 1k, the capacitive element C_{DESAT} (see FIG. 1) is omitted, and instead, a capacitive element C_{DESAT1} is added to the protection circuit 4k. The capacitance value of the capacitive element C_{DESAT1} can be determined in advance according to a charging characteristic of the capacitive element C_{DESAT1} required for detecting a fall in a voltage at the one end D of the power device PT.

In this manner, in the semiconductor integrated circuit 2p of the semiconductor device 1p, configuration is simplified by configuring the protection circuit 4p including the detection circuit 3p. As a result, the circuit scale of the semiconductor integrated circuit 2p can be reduced, thereby being able to save the space of the semiconductor device 1p and being able to reduce the cost of the semiconductor device 1p.

In the configuration illustrated in FIG. 10, the capacitive element C_{DESAT1} may be omitted. In this case, the current source 43 of the protection circuit 4p charges the current to the parasitic capacitance of the line connecting the comparison circuit 41 and the terminal DESAT.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A detection circuit comprising:
a comparison circuit having a first input node connected to one end of a power device, a second input node connected to a threshold voltage corresponding to a fall in a waveform, and an output node; and
a signal generation circuit having a first input node connected to the output node of the comparison circuit and an output node connected to a control node of a protection circuit of the power device.

2. The detection circuit according to claim 1, wherein
the signal generation circuit generates a control signal for enabling the protection circuit as a comparison result of the comparison circuit is inverted.

3. The detection circuit according to claim 2, wherein
the signal generation circuit supplies the control signal at a non-active level to the protection circuit in a first period in which the comparison circuit outputs a first comparison result, and supplies the control signal at an active level to the protection circuit in a second period in which the comparison circuit outputs a second comparison result inverted from the first comparison result.

4. The detection circuit according to claim 1, wherein
the signal generation circuit further has a second input node connected to an input terminal.

5. The detection circuit according to claim 4, wherein
the signal generation circuit measures a time from a rise in a waveform of an input signal supplied to the input terminal until a comparison result of the comparison circuit is inverted, and generates a signal for enabling the protection circuit as a predetermined time corresponding to the measured time has elapsed from the rise in the waveform of the input signal.

6. The detection circuit according to claim 5, wherein
the signal generation circuit generates the signal for enabling the protection circuit as the comparison result of the comparison circuit is inverted or as the predetermined time has elapsed from the rise in the waveform of the input signal.

7. A semiconductor integrated circuit comprising:
the detection circuit according to claim 1;
a protection circuit having an input node connected to one end of a power device, a control node connected to an output node of the detection circuit, and an output node; and
a drive circuit having an input node connected to an input terminal, a control node connected to the output node of the protection circuit, and an output node connected to a control terminal of the power device.

8. A semiconductor integrated circuit comprising:
a drive circuit having an input node, a control node, and an output node connected to a control terminal of a power device;
a first comparison circuit having a first input node connected to one end of the power device, a second input node connected to a first threshold voltage corresponding to a fall in a waveform, and an output node;
a second comparison circuit having a first input node connected to one end of the power device, a second input node connected to a second threshold voltage corresponding to a rise in a waveform, and an output node; and
a signal generation circuit having a first input node connected to the output node of the first comparison circuit, a first output node, and a second output node connected to the control node of the drive circuit.

9. The semiconductor integrated circuit according to claim 8, further comprising
a switch having a first node connected to the first input node of the second comparison circuit, a second node connected to a reference potential, and a control node,
wherein the signal generation circuit generates a signal for enabling the protection circuit as a comparison result of the first comparison circuit is inverted.

10. The semiconductor integrated circuit according to claim 8, further comprising
a switch having a first node connected to the first input node of the second comparison circuit, a second node connected to a reference potential, and a control node,
wherein the signal generation circuit measures a time from a rise in a waveform of an input signal of the drive circuit to a fall in a waveform of a voltage at one end of the power device, and generates a signal for enabling the protection circuit as a predetermined time corresponding to the measured time has elapsed from the rise in the waveform of the input signal.

11. The semiconductor integrated circuit according to claim 10, wherein
the signal generation circuit generates a signal for enabling the protection circuit as a comparison result of the first comparison circuit is inverted or as the predetermined time has elapsed from the rise in the waveform of the input signal.

12. A semiconductor device comprising:
the semiconductor integrated circuit according to claim 7;
a first rectifier element connected between a detection circuit and one end of the power device; and
a second rectifier element connected between a protection circuit and one end of the power device.

13. A semiconductor device comprising:
the semiconductor integrated circuit according to claim 8; and
a rectifier element connected between the first input node of the second comparison circuit and one end of the power device.

14. A control method comprising:
comparing a voltage at one end of a power device with a threshold voltage; and
enabling a protection circuit of the power device as a result of the comparison is inverted.

15. The control method according to claim 14, further comprising
measuring a time from a rise in a waveform of an input signal to a fall in a waveform of a voltage at one end of the power device as the result of the comparison is inverted,
wherein the enabling of the protection circuit includes enabling the protection circuit in response to the result of the comparison is inverted and/or to a predetermined time corresponding to the measured time has elapsed from the rise in the waveform of the input signal.
